(19) United States
(12) Patent Application Publication
(10) Pub. No.: US 2024/0363821 A1
(43) Pub. Date: Oct. 31, 2024

(54) LED DISPLAY DEVICE ARRAY, LED DISPLAY DEVICE, AND DISPLAY PANEL

(71) Applicant: FOSHAN NATIONSTAR OPTOELECTRONICS CO., LTD., Guangdong (CN)

(72) Inventors: Kuai QIN, Guangdong (CN); Shaojia XIE, Guangdong (CN); Bin CAI, Guangdong (CN); Hongwen CHEN, Guangdong (CN); Zhuang PENG, Guangdong (CN); Kailiang FAN, Guangdong (CN)

(21) Appl. No.: 18/648,434

(22) Filed: Apr. 28, 2024

(30) Foreign Application Priority Data
Apr. 28, 2023 (CN) 202321031878.2
Aug. 24, 2023 (CN) 202322292211.4

(51) Int. Cl. H01L 33/62; H01L 25/075

(52) U.S. Cl. CPC H01L 33/62; H01L 25/0753

(57) ABSTRACT

An LED display device array includes a substrate, at least two display units disposed on the upper surface of the substrate, and pin assemblies disposed on the lower surface of the substrate and in one-to-one correspondence with the at least two display units, a cutting line is disposed on the substrate between any two adjacent pin assemblies. Each of the pin assemblies includes at least two pins, and the at least two pins are a first pin and a second pin separately. A first pin in a pin assembly is misaligned with a second pin in an adjacent pin assembly, and the first pin and the second pin are connected to each other by a connecting wire. The connecting wire has a linear connecting segment, and the connecting segment of the connecting wire intersects with the cutting line and is perpendicular to the cutting line.

### CROSS-REFERENCE TO RELATED APPLICATION(S)

This application claims the priority of a Chinese Patent Application No. 202321031878.2, filed on Apr. 28, 2023, and the priority of a Chinese Patent Application No. 202322292211.4, filed on Aug. 24, 2023, the disclosure of both of which are incorporated herein by reference in their entirety.

### TECHNICAL FIELD

The present application relates to the field of a light-emitting diode (LED) display technology and, in particular, to an LED display device array, an LED display device, and a display panel.

### BACKGROUND

With the rapid development of LED display technologies, LED display screens have been widely used in commercial activities and various aspects of life, and the market demand for LED display screens is ever-increasing. To implement mass production of LED beads, it is common to die-bond multiple pixel assemblies including light-emitting chips on the upper surface of one complete substrate to form multiple independent display units, pin assemblies in one-to-one correspondence with the display units are formed on the lower surface of a circuit board through electroplating, and each of the pin assemblies includes multiple pins. Cutting lines in the shape of a square grid are disposed on the upper surface of the substrate to cutting the substrate using a display unit as a cutting unit. After the display units are filled with encapsulants, the display units are cut by a dicing saw along the cutting lines so that a single LED bead is formed.

### SUMMARY

An LED display device array includes a substrate, at least two display units disposed on the upper surface of the substrate, and at least two pin assemblies that are disposed on the lower surface of the substrate and are in one-to-one correspondence with the at least two display units, where a cutting line is disposed on the substrate between any two adjacent pin assemblies. Each of the pin assemblies includes at least two pins, and the at least two pins include a first pin and a second pin. A first pin in one of the at least two pin assemblies is misaligned with a second pin in an adjacent one of the at least two pin assemblies, where the first pin and the second pin are connected to each other through a connecting wire. The connecting wire has a linear connecting segment, and the connecting segment of the connecting wire intersects with the cutting line and is perpendicular to the cutting line.

In some embodiments, the length of the connecting segment of the connecting wire is greater than the width of the cutting line.

In some embodiments, the connecting wire further has a first pin connecting segment and a second pin connecting segment, where one end of the first pin connecting segment is connected to the first pin, and the other end of the first pin connecting segment is connected to one end of the connecting segment, and one end of the second pin connecting segment is connected to the second pin, and the other end of the second pin connecting segment is connected to the other end of the connecting segment.

In some embodiments, each of the first pin connecting segment and the second pin connecting segment is a straight line or a curve.

In some embodiments, each of the first pin connecting segment and the second pin connecting segment is a straight line, and the first pin connecting segment and the second pin connecting segment are perpendicular to the connecting segment.

In some embodiments, each of the first pin connecting segment and the second pin connecting segment is a straight line, the first pin connecting segment is perpendicular to the connecting segment, and the second pin connecting segment is collinear with the connecting segment, or the second pin connecting segment is perpendicular to the connecting segment, and the first pin connecting segment is collinear with the connecting segment.

In some embodiments, the LED display device array includes a cover plate that covers the upper surface of the substrate, where a cover plate is provided with through holes, and a through hole forms an accommodation cavity with the substrate, and a display unit includes at least one pixel assembly, and each of the at least one pixel assembly is disposed in a respective accommodation cavity.

In some embodiments, the accommodation cavity is filled with an encapsulant, and the encapsulant is transparent and black.

In some embodiments, the accommodation cavity is filled with an encapsulant, and the encapsulant includes a first encapsulant layer at a lower portion of the accommodation cavity and a second encapsulant layer at an upper portion of the accommodation cavity, where the first encapsulant layer is transparent, and the second encapsulant layer is transparent and black.

In some embodiments, at least one pad assembly is disposed on the upper surface of the substrate, the at least one pad assembly is in one-to-one correspondence with the at least one pixel assembly, the pixel assembly is die-bonded on the pad assembly, and the periphery of the pad assembly in the accommodation cavity is a circular structure adapted to the bottom of the accommodation cavity.

In some embodiments, the substrate is provided with a conductive hole penetrating through the upper surface of the substrate and the lower surface of the substrate, and the pad assembly and the pin assembly are electrically connected to each other through the conductive hole, the lower surface of the substrate is divided into an insulating region and a non-insulating region, and the pin assembly further includes a pin wire configured to connect a pin to the conductive hole, the pin is disposed in the non-insulating region, the insulating region is covered with solder resist ink, and the solder resist ink covers the pin wire in the insulating region.

In another aspect, the present application further provides an LED display device, where any LED display device array mentioned above is cut along the cutting line such that the LED display device is formed.

The present application adopts the technical solution described below.

An LED display device includes a substrate, a circuit assembly, a pin assembly, at least one RGB chip group, and a metal identifier.

The substrate has an upper surface and a lower surface, where the upper surface includes a wiring region and a non-wiring region.

The circuit assembly is disposed on the upper surface of the substrate and includes a metal wire and at least one pad assembly connected to the metal wire, where the metal wire is disposed in the wiring region, and the at least one pad assembly is disposed in the non-wiring region.

The pin assembly is disposed on the lower surface of the substrate and connected to the circuit assembly through a conductive hole penetrating through the substrate.

The at least one RGB chip group is disposed on the at least one pad assembly, respectively.

The metal identifier is used for identifying the position of the at least one RGB chip group in the substrate, fixed in the non-wiring region, and connected to the metal wire by a connecting metal wire.

In some embodiments, the LED display device further includes a black ink layer, where the black ink layer is disposed on the upper surface of the substrate and covers the metal wire and the connecting metal wire.

In some embodiments, the RGB chip group includes a red LED chip, a green LED chip, and a blue LED chip, where each of the red LED chip, the green LED chip, and the blue LED chip is a flip chip.

In some embodiments, the pad assembly includes three pairs of pads, the three pairs of pads are correspondingly connected to the red LED chip, the green LED chip, and the blue LED chip respectively, two pads in each pair of pads are axisymmetrically disposed, and midlines of the two pads in the each pair are on the same straight line.

In some embodiments, the conductive hole includes a common-electrode conductive hole, where the common-electrode conductive hole is connected to electrodes of the same polarity of all chips in the at least one RGB chip group through the metal wire and the pad assembly.

In some embodiments, the metal identifier is connected to the common-electrode conductive hole through the connecting metal wire.

Another object of the present application is to further provide a display panel including the LED display device mentioned above.

### BRIEF DESCRIPTION OF DRAWINGS

FIG. 1 is a schematic diagram of a back structure of an LED display device array;

FIG. 2 is a schematic diagram of a back structure of a single LED display device in an LED display device array in the present application;

FIG. 3 is a schematic diagram of a back structure of an LED display device array in the present application;

FIG. 4 is a structural diagram showing an embodiment of a connecting wire between two pins misaligned with each other in an LED display device array in the present application;

FIG. 5 is a structural diagram showing an embodiment of a connecting wire between two pins misaligned with each other in an LED display device array in the present application;

FIG. 6 is a structural diagram showing an embodiment of a connecting wire between two pins misaligned with each other in an LED display device array in the present application;

FIG. 7 is a structural diagram showing an embodiment of a connecting wire between two pins misaligned with each other in an LED display device array in the present application;

FIG. 8 is a structural diagram showing an embodiment of a connecting wire between two pins misaligned with each other in an LED display device array in the present application;

FIG. 9 is a sectional view of a single LED display device with a cover plate in an LED display device array in the present application;

FIG. 10 is a schematic diagram of a front structure of a single LED display device with a cover plate in an LED display device array in the present application;

FIG. 11 is a structural diagram of a single LED display device with its back covered with solder resist ink in an LED display device array in the present application;

FIG. 12 is a schematic diagram of a side surface of a conventional display device;

FIG. 13A and FIG. 13B are structural diagrams of the upper surface of an LED display device in the present application, where FIG. 13A shows the upper surface of the LED display device omitting an encapsulant, and FIG. 13B shows the upper surface of the LED display device omitting the encapsulant and a black ink layer;

FIG. 13C and FIG. 13D are structural diagrams of the lower surface of an LED display device in the present application, where FIG. 13D shows the lower surface of the LED display device omitting a solder resist layer;

FIG. 14A and FIG. 14B are structural diagrams of the upper surface of an LED display device in the present application, where FIG. 14A shows the upper surface of the LED display device omitting an encapsulant, and FIG. 14B shows the upper surface of the LED display device omitting the encapsulant and a black ink layer; and

FIG. 14C and FIG. 14D are structural diagrams of the lower surface of an LED display device in the present application, where FIG. 14D shows the lower surface of the LED display device omitting a solder resist layer and a white ink layer.

### REFERENCE LIST

1′ LED bead substrate that is not cut
2′ pin on the lower surface of the LED bead substrate
3′ cutting line on the substrate
4′ connecting wire connecting two pins
10 substrate
100 cutting line
101 conductive hole
10a insulating region
10b non-insulating region
200 pixel assembly
30 pin assembly
31 first pin assembly
32 second pin assembly
33 third pin assembly
34 fourth pin assembly
300 pin
310 pin wire
311 first pin in the first pin assembly
312 second pin in the first pin assembly
313 third pin in the first pin assembly
321 first pin in the second pin assembly
322 second pin in the second pin assembly
323 third pin in the second pin assembly
400 connecting wire
4001 first pin connecting segment
4002 second pin connecting segment
4003 connecting segment
50 cover plate
500 through hole
10′ substrate of an LED display device
100′ encapsulant
2 circuit assembly
21 metal wire
22 pad assembly
101a common-electrode conductive hole
101b pad conductive hole
5 RGB chip group
51 red LED chip
52 green LED chip
53 blue LED chip
6 metal identifier
60 connecting metal wire
7 black ink layer
91 solder resist layer
92 window
93 white ink layer

### DETAILED DESCRIPTION

The present application is further described in detail below in conjunction with drawings and embodiments. It is to be understood that the embodiments described here are intended to illustrate the present application and not to limit the present application. Additionally, it is to be noted that for ease of description, only part, not all, of structures related to the present application is illustrated in the drawings.

In the description of the present application, the terms “joined”, “connected”, and “fixed” are to be understood in a broad sense unless otherwise expressly specified and limited. For example, the term “connected” may refer to “fixedly connected”, “detachably connected”, or “integrated”, may refer to “mechanically connected” or “electrically connected”, or may refer to “connected directly”, “connected indirectly through an intermediary”, “connected inside two components”, or “interactional between two components”. For those of ordinary skill in the art, specific meanings of the preceding terms in the present application may be understood based on specific situations.

In the present application, unless otherwise expressly specified and limited, when a first feature is described as “above” or “below” a second feature, the first feature and the second feature may be in direct contact, or be in contact via another feature between the two features. Moreover, when the first feature is described as “on”, “above”, or “over” the second feature, the first feature is right on or obliquely on the second feature, or the first feature is simply at a higher level than the second feature. When the first feature is described as “under”, “below”, or “underneath” the second feature, the first feature is right under, below, or underneath the second feature or the first feature is obliquely under, below, or underneath the second feature, or the first feature is simply at a lower level than the second feature.

In the description of the embodiments, orientations or position relations indicated by terms such as “above”, “below”, “left”, and “right” are based on the drawings. These orientations or position relations are intended only to facilitate the description and simplify an operation and not to indicate or imply that an apparatus or element referred to must have such particular orientations or must be configured or operated in such particular orientations. Therefore, these orientations or position relations are not to be construed as limiting the present application. Moreover, the terms “first” and “second” are only used for distinguishing between descriptions and have no special meanings.

During the actual production of LED beads, it is common to connect pins between adjacent pin assemblies in series using connecting wires, enabling uniform electroplating of tin on each pin. To reduce the length of the connecting wire, they are typically straight segments. However, for two adjacent pins that are misaligned, the straight connecting wire between the two pins is not perpendicular to the cutting line disposed on the upper surface of the substrate. Therefore, when the connecting wire is cut along this line, it produces an uneven and slanted cut, which can easily lead to a burr defect.

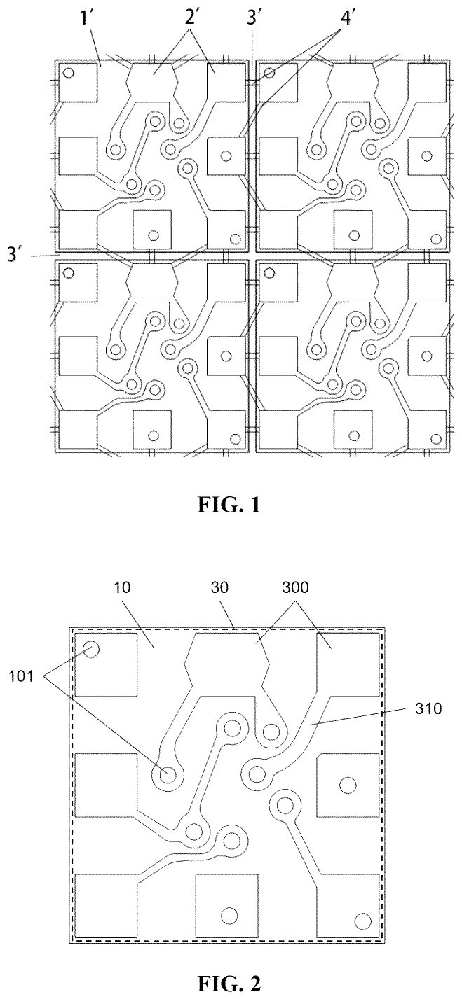

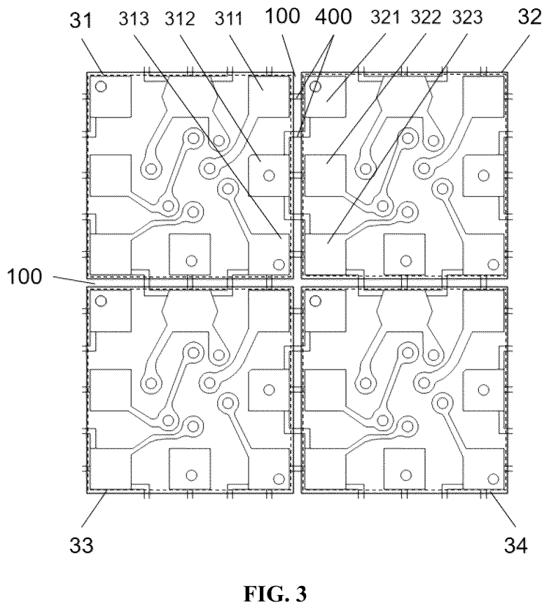

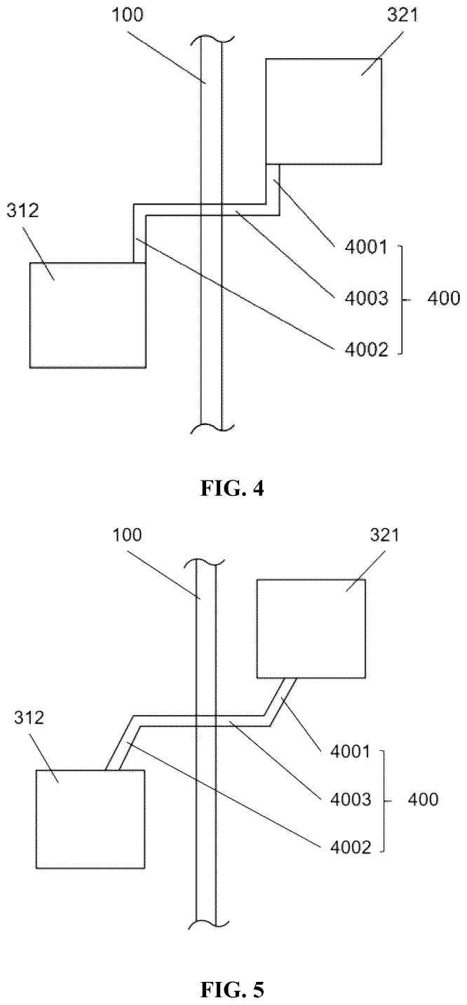

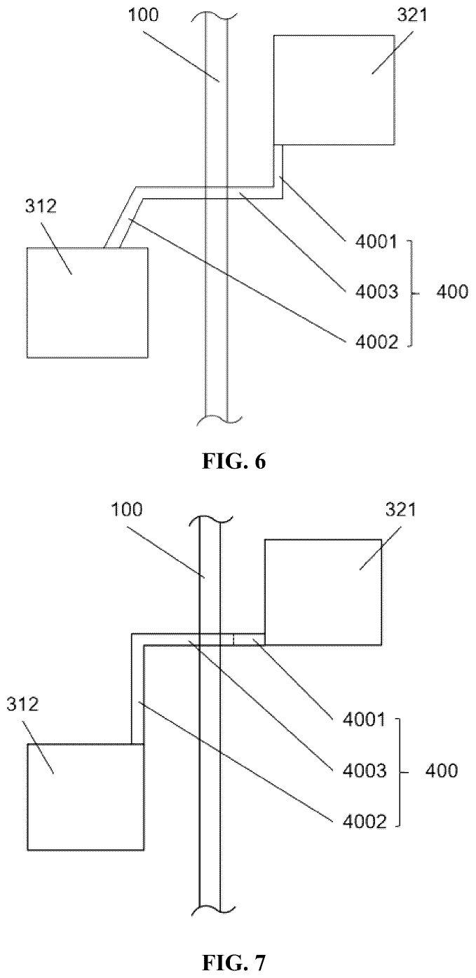

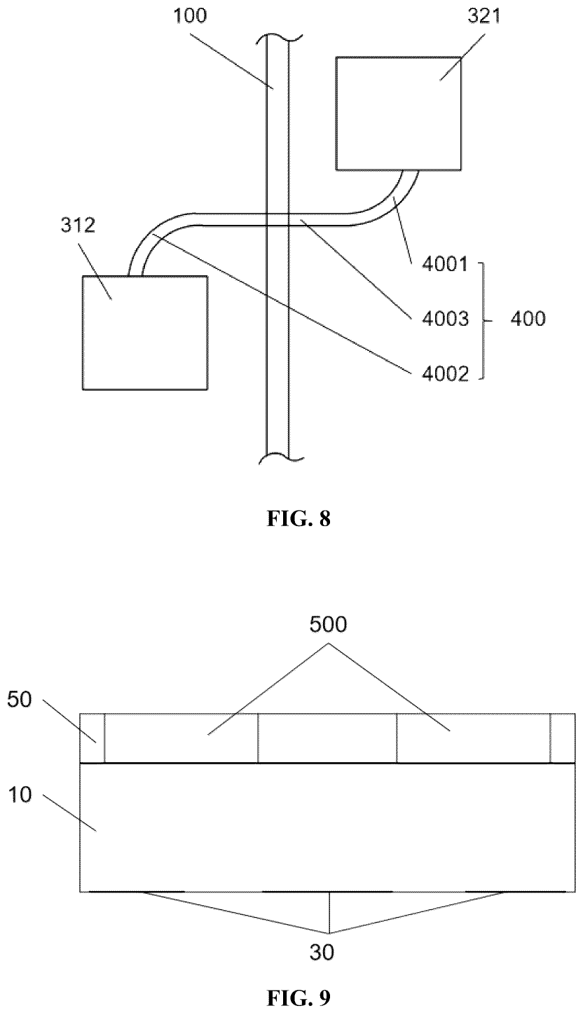

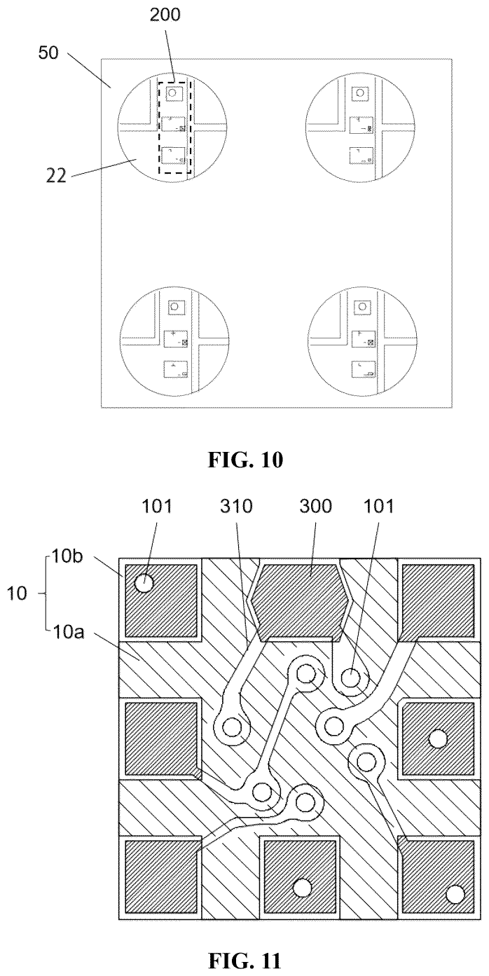

As an example, referring to FIG. 1, when the pin assembly is formed through electroplating, pins 2′ between adjacent pin assemblies are connected in series through a connecting wire 4′ so that pins 2′ in each pin assembly are uniformly electroplated with tin. To reduce the length of the connecting wire, each of connecting wires 4′ is straight as shown in FIG. 1. However, for two adjacent pins 2′ that are misaligned as shown in FIG. 1, the connecting wire between the two pins 2′ is oblique to a cutting line 3. Therefore, when the connecting wire is cut along this line, it produces an uneven and slanted cut a burr defect, which can easily lead to a burr defect.

Based on this, the present application provides an LED display device array, where part of a connecting wire intersecting with a cutting line is configured to be perpendicular to the cutting line so that a cut of the connecting wire formed after the connecting wire is cut along the cutting line is even, thereby avoiding the burr defect.

FIGS. 2 to 4 show specific structures of an embodiment of the LED display device array in the present application. As shown in FIGS. 2 to 4, the LED display device array includes a substrate 10, four groups of display units and pin assemblies 30. The four groups of display units disposed on the upper surface of the substrate 10. The pin assemblies 30 are disposed on the lower surface of the substrate 10 and are in one-to-one correspondence with the display units. The four groups of display units are distributed in a matrix with two rows and two columns on the upper surface of the substrate 10. In order to cut the display units distributed in the matrix to form a single LED display device, each of cutting lines 100 in the shape of a square grid is provided on the upper surface of the substrate 10 at a position located between two adjacent pin assemblies 30. When the display units are cut along the cutting lines 100, all the display units and the pin assemblies 30 corresponding to the display units can be separated from each other such that the single LED display device is formed. The cutting line 100 is a linear groove provided on the substrate 10. Of course, the cutting line 100 may be a two-dimensional identifier on the surface of the substrate 10.

As shown in FIG. 3, cutting lines 100 in the shape of a cross are used as boundaries, and the four pin assemblies 30 corresponding to the four groups of display units are also distributed in a matrix with two rows and two columns, which are a first pin assembly 31, a second pin assembly 32, a third pin assembly 33, and a fourth pin assembly 34. Each of the four pin assemblies 30 includes eight pins. In the first row, a first pin 311 of the first pin assembly, a second pin 312 of the first pin assembly, and a third pin 313 of the first pin assembly are disposed on the substrate 10 on the left side of the cutting line 100, and a first pin 321 of the second pin assembly, a second pin 322 of the second pin assembly, and a third pin 323 of the second pin assembly are distributed on the substrate 10 on the right side of the cutting line 100, and are symmetrically distributed on the substrate 10 with the first pin 311 of the first pin assembly, the second pin 312 of the first pin assembly, and the third pin 313 of the first pin assembly respectively. The second pin 312 of the first pin assembly and the first pin 321 of the second pin assembly misaligned with each other are connected to each other through a connecting wire 400. Here, the misalignment between two pins 300 refers to that for the two pins 300 on two sides of the cutting line 100, the extension surface of one pin 300 along a direction perpendicular to the adjacent cutting line 100 does not overlap the extension surface of the other pin 300 along the direction perpendicular to the adjacent cutting line 100.

The connecting wire 400 includes a first pin connecting segment 4001 and a second pin connecting segment 4002 that are opposite to each other, and a connecting segment 4003 connecting the first pin connecting segment 4001 to the second pin connecting segment 4002. Specifically, the connecting segment 4003 is straight, intersects with the cutting line 100, and is perpendicular to the cutting line 100. The first pin connecting segment 4001 and the second pin connecting segment 4002 are also straight. One end of the first pin connecting segment 4001 is connected to the first pin 321 of the second pin assembly, and the other end of the first pin connecting segment 4001 is connected to one end of the connecting segment 4003, and one end of the second pin connecting segment 4002 is connected to the second pin 312 of the first pin assembly, and the other end of the second pin connecting segment 4002 is connected to the other end of the connecting segment 4003. The connecting wire 400 having such a structure can connect the pins 300 that are between the adjacent pin assemblies 30 and are misaligned with each other, and it is ensured that the portion of the connecting wire 400 intersecting with the cutting line 100 is perpendicular to the cutting line 100. Further, it is ensured that the connecting wire 400 has an even cut after being cut along the cutting line 100, thereby avoiding the burr defect. Similarly, the second pin 312 of the first pin assembly and the third pin 323 of the second pin assembly are also connected to each other by a connecting wire 400 having the same structure.

In some embodiments, the first pin connecting segment 4001 and the second pin connecting segment 4002 may be each perpendicular to the connecting segment 4003 as shown in FIGS. 3 and 4 such that the I-shaped connecting wire 400 is formed. In some embodiments, as shown in FIG. 5, neither the first pin connecting segment 4001 nor the second pin connecting segment 4002 may be perpendicular to the connecting segment 4003. In some embodiments, as shown in FIG. 6, the first pin connecting segment 4001 (or the second pin connecting segment 4002) may be perpendicular to the connecting segment 4003, and the second pin connecting segment 4002 (or the first pin connecting segment 4001) may be not perpendicular to the connecting segment 4003. In some embodiments, as shown in FIG. 7, the first pin connecting segment 4001 (or the second pin connecting segment 4002) may be perpendicular to the connecting segment 4003, and the second pin connecting segment 4002 (or the first pin connecting segment 4001) may be collinear with the connecting segment 4003 such that an L-shaped connecting wire 400 is formed. Of course, in addition to being straight lines, the first pin connecting segment 4001 and the second pin connecting segment 4002 may be curves as shown in FIG. 8. Specifically, the first pin connecting segment 4001 and the second pin connecting segment 4002 may be adjusted according to a circuit design and are not uniquely limited here as long as it is ensured that the connecting segment 4003 of the connecting wire 400 intersecting with the cutting line 100 is a straight line and perpendicular to the cutting line 100. In some embodiments, the connecting wire 400 connecting the pins 300 misaligned with each other is preferably the shortest I-shaped connecting wire so that manufacturing difficulties and the manufacturing costs are reduced.

In some embodiments, the length of the connecting segment 4003 is greater than the width of the cutting line 100 so that a dicing saw is prevented from cutting the connecting wire 400 from an end surface of the connecting wire 400.

Of course, when pins are formed through electroplating, a connecting wire is also disposed between pins that are on the two sides of the cutting line 100 and opposite to each other. As shown in FIG. 3, the first pin 311 of the first pin assembly and the first pin 321 of the second pin assembly are connected to each other through a connecting wire 400 in the shape of a straight line, and the connecting wire 400 in the shape of a straight line intersects with the cutting line 100. The second pin 312 of the first pin assembly and the second pin 322 of the second pin assembly that are aligned with each other are connected to each other by a straight connecting wire 400, and the straight connecting wire 400 is perpendicular to the cutting line 100. The third pin 313 of the first pin assembly and the third pin 323 of the second pin assembly aligned with each other are connected to each other by a straight connecting wire 400, and the straight connecting wire 400 is perpendicular to the cutting line 100. Here, the connecting wire 400 in the shape of a straight line means that the first pin connecting segment 4001 and the second pin connecting segment 4002 are each collinear with the connecting segment 4003, which is actually a special variant of the preceding connecting wire 400.

Similarly, two pins 300 that are in the first pin assembly 31 and the adjacent third pin assembly 33 and aligned to each other are also connected to each other by a connecting wire 400 in the shape of a straight line, and two pins 300 that are in the second pin assembly 32 and the adjacent fourth pin assembly 34 and aligned with each other are also connected to each other by a connecting wire 400 in the shape of a straight line. Pins 300 that are in the first pin assembly 31 and the adjacent third pin assembly 33 and are misaligned with each other are also connected to each other by an I-shaped connecting wire 400, and pins 300 that are in the second pin assembly 32 and the adjacent fourth pin assembly 34 and are misaligned with each other are also connected to each other by an I-shaped connecting wire 400. The details are not repeated here.

In this way, the connecting wire 400 with the linear connecting segment 4003 is disposed between the pins 300 that are in the pin assemblies 30 adjacent to each other and are at different positions, and it is ensured that the connecting segment 4003 of the connecting wire 400 is perpendicular to the cutting line 100. Thus, it is ensured that the connecting wire 400 has the even cut after being cut along the cutting line 100, and the burr defect is avoided.

It is to be noted that in the preceding LED display device array, the number of pins 300 included in each pin assembly 30 is not limited to eight. Each pin assembly 30 may include two to seven pins or more than eight pins, which is not uniquely limited here.

In some embodiments, as shown in FIGS. 9 and 10, the preceding LED display device array further includes a cover plate 50. The cover plate 50 covers the upper surface of the substrate 10 and is corresponding to the display unit. Specifically, the cover plate 50 is adhered to the upper surface of the substrate 10 by epoxy resin, the cover plate 50 is provided with four through holes 500, and each of the through holes 500 forms an accommodation cavity with the substrate 10. The display units include four pixel assemblies 200 that are in one-to-one correspondence with four accommodation cavities. Each pixel assembly 200 is disposed in a respective accommodation cavity. A pixel assembly 200 specifically includes light-emitting chips of different colors. The accommodation cavity is filled with an encapsulant to isolate air and vapor. However, the encapsulant and the substrate 10 are less adhesive to each other, so vapor is prone to enter the light-emitting chips in the pixel assembly 200 via the gap between the substrate and the encapsulant. The LED display device in some embodiments has the cover plate 50 covering the top of the substrate 10 so that the contact area between the encapsulant and outside is reduced and vapor from outside is prevented from entering the light-emitting chips in the pixel assembly 200 via the gap between the substrate 10 and the encapsulant. In addition, the cover plate 50 has greater mechanical strength and a remarkable ability to resist impact and is not prone to deformation, damage, or the like so that the stability of the device is improved.

Optionally, the through hole 500 is cylindrical. The through hole 500 with a cylindrical structure can reduce the deflection of light emitted from the light-emitting chips in the through hole 500 so that the range in which the light diverges is controlled, thereby causing the light to be more concentrated.

In some embodiments, the encapsulant filled in the accommodation cavity may be transparent and black. The encapsulant is mixed with a blackening agent. The blackening agent has a black appearance but allows light to pass through the encapsulant. The blackening agent is a black additive that uses epoxy resin as a matrix and is mixed with a nano inorganic pigment, which can change the blackness of the encapsulant. The encapsulant that is transparent and black is filled in the accommodation cavity to increase the blackness of the surface of the encapsulant, thereby increasing the contrast ratio of the display unit.

Of course, if the encapsulant is excessively black, the brightness of the display unit will be affected. For the balance between the brightness of the display unit and the blackness of the display unit, the encapsulant filled in the accommodation cavity preferably includes a first encapsulant layer at a lower portion of the accommodation cavity and a second encapsulant layer at an upper portion of the accommodation cavity, where the first encapsulant layer is transparent, and the second encapsulant layer is transparent and black. Since the transparent first encapsulant layer is close to the light-emitting chips, the light emitting efficiency of the light-emitting chips can be improved, and the second encapsulant layer close to the opening of the accommodation cavity can increase the blackness of the appearance of the display unit to increase the contrast ratio. Further, the second encapsulant layer has a thickness of 0.05 mm to 0.1 mm so that the brightness of the display unit and the contrast ratio of the display unit are kept balanced. If the second encapsulant layer is excessively thick, such a second encapsulant layer is conducive to increasing the contrast ratio of the display unit but reduces the brightness of the display unit. On the contrary, if the second encapsulant layer is excessively thin, such a second encapsulant layer is conducive to improving the brightness of the display unit but decreases the contrast ratio of the display unit.

In some embodiments, four pad assemblies 22 are disposed on the upper surface of the substrate 10 and are in one-to-one correspondence with the pixel assemblies 200. The substrate 10 is further provided with conductive holes 101 penetrating through the upper surface of the substrate 10 and the lower surface of the substrate 10. The pad assembly 22 and a respective pin assembly 30 are electrically connected to each other by a conductive hole 101. The light-emitting chips in the pixel assembly 200 are die-bonded on the pad assembly 22. The periphery of the pad assembly 22 in the accommodation cavity is a circular structure adapted to the bottom of the accommodation cavity. That is, the bottom of the accommodation cavity is filled with the pad assembly 22. In this way, compared with a pad assembly 22 in another shape, the pad assembly 22 of the circular structure has the periphery adapted to the bottom of the accommodation cavity so that a light concentration effect can be improved.

As a pin wire 310 is relatively close to an adjacent pin 300, therefore, in the process of solder electroplating on the pin 300, excessive solder paste or deviation of solder paste in the process, will cause the pin wire 310 and the pin 300 to be easily connected to each other to cause a short circuit. Therefore, in some embodiments, as shown in FIG. 11, the lower surface of the substrate 10 is divided into an insulating region 10a and a non-insulating region 10b. The pin assembly 30 further includes pin wires 310 configured to connect the pins 300 to conductive holes 101. The pins 300 are disposed in the non-insulating region 10b, and the pin wires 310 are disposed in the insulating region 10a. The insulating region 10a is covered with solder resist ink, and the solder resist ink covers the pin wires 310 in the insulating region 10a. In this manner, the pin wires 310 are covered with a layer of solder resist ink to prevent the pin wires 310 and adjacent pins 300 from being connected to each other to cause short circuits.

In addition, the present application further provides an LED display device, and the LED display device is formed by cutting any LED display device array mentioned above along the cutting line.

Compared with the related art, the LED display device array and the LED display device in the present application have the benefits described below.

The connecting wire 400 with the straight connecting segment 4003 is disposed between the two pins that are in the two adjacent pin assemblies 30 and are misaligned with each other, and it is ensured that the straight connecting segment 4003 intersecting with the cutting line on the substrate is perpendicular to the cutting line so that the connecting wire 400 has the even cut after being cut along the cutting line, and the burr defect is avoided.

The cover plate 50 and the substrate are pressed together and the accommodation cavity capable of accommodating the pixel assembly 200 is formed on the cover plate 50 so that the contact area between the encapsulant and the substrate is reduced and vapor from the outside is prevented from entering the light-emitting chips in the pixel assembly 200 via the gap between the substrate and the encapsulant. In addition, the mechanical strength of the device can be improved so that the stability of the device is improved.

The solder resist region and the non-solder resist region are disposed on the lower surface of the substrate, and the solder resist region is covered with the solder resist ink so that the pin wires 310 in the solder resist region are not in contact with the adjacent pins in the non-solder resist region. Thus, when the pins are electroplated with tin, the case that the solder paste flows along the pin wires 310, causing the pin wires 310 to be in contact with the adjacent pins to cause the short circuits is avoided.

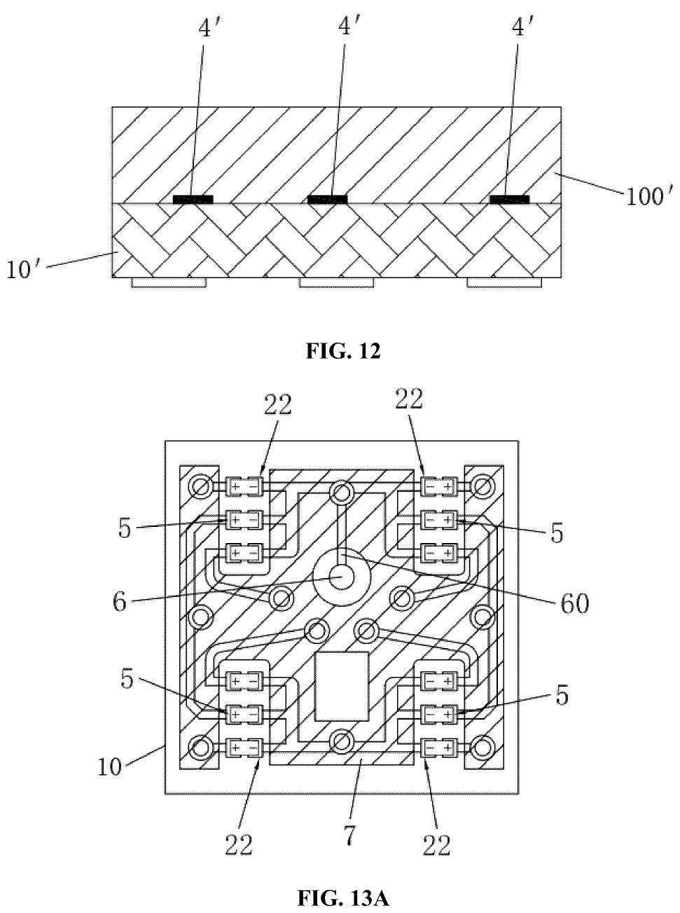

In a conventional mini LED display device, an identification point is generally disposed on the upper surface of a substrate and is used for identifying the position of an LED chip in the substrate. However, the identification point disposed is usually isolated and is prone to fall off when the substrate is cleaned, failing to perform the function of positioning the chip. Moreover, as shown in FIG. 12, in a circuit electroplating process of such type of device, connecting wires 4′ are disposed on the upper surface of a substrate 10′ where chips are mounted, and then multiple positions where the vapor can easily enter exist at the joint between an encapsulant 100′ on the upper surface and the substrate 10′ after encapsulation, that is, the positions where the ends of the connecting wires 4′ extends out of a side surface of the encapsulant 100′. The reliability of a product is reduced by the positions where the vapor can easily enter. In addition, face-up chips are used in most devices at present. The face-up chips need to be bonded with gold wires. Not only is the manufacturing process complicated, but the existence of the gold wires affects the brightness of the product and the contrast ratio of the product. In addition, defects such as gold migration are prone to appear.

In the light of at least one drawback of the related art, the present application provides an LED display device, where a metal identifier disposed in the LED display device is firmly combined with a substrate and is not prone to fall off so that the metal identifier can reliably perform the function of positioning chips.

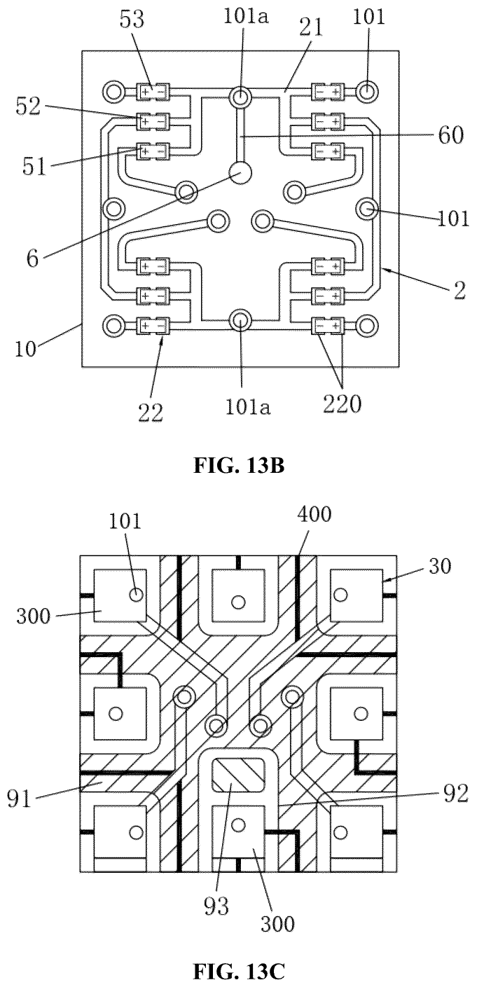

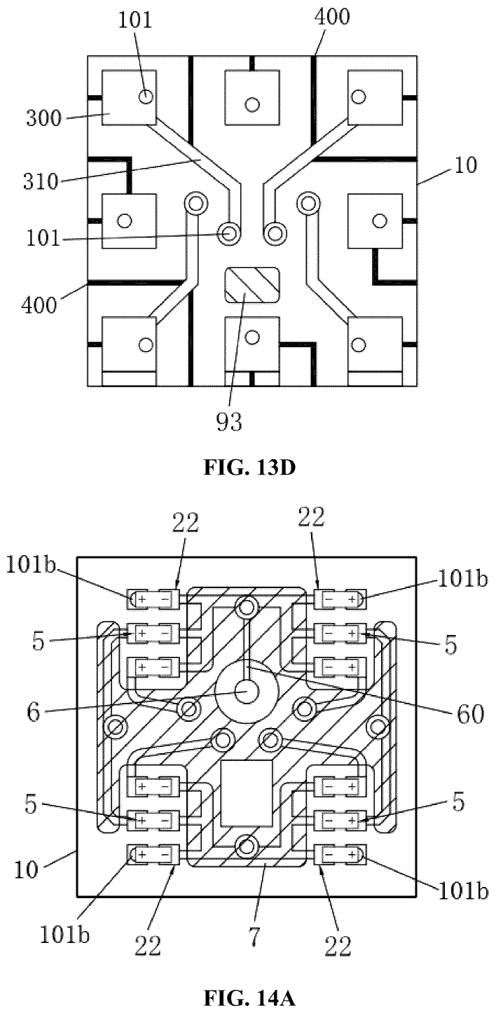

Referring to FIGS. 13A to 13D, an LED display device includes a substrate 10, a circuit assembly 2, a pin assembly 30, at least one RGB chip group 5, a metal identifier 6, a black ink layer 7, an encapsulant (not shown in the figures), a connecting wire 400, and a white ink layer 93. The substrate 10 has an upper surface and a lower surface that are opposite to each other, where the upper surface is the upper surface of the device, and the lower surface is the lower surface of the device.

To facilitate clear observation of the arrangement of various components on both the upper and lower surfaces of the substrate 10, FIG. 13A shows the upper surface of the LED display device omitting the encapsulant, where the portion filled with oblique lines in this figure represents the black ink layer 7, FIG. 13B shows the upper surface of the LED display device omitting the encapsulant and the black ink layer 7, FIG. 13C shows the lower surface of the LED display device, where the large-area portion filled with oblique lines in this figure represents a solder resist layer 91, and the small-area portion filled with oblique lines represents the white ink layer 93, and FIG. 13D shows the lower surface of the LED display device omitting the solder resist layer 91.

As shown in FIGS. 13A and 13B, the circuit assembly 2 is disposed on the upper surface of the substrate 10. The circuit assembly 2 includes a metal wire 21 and one or more pad assemblies 22. The metal wire 21 and the pad assemblies 22 are connected to each other. The metal wire 21 is arranged on the upper surface of the substrate 10. The region occupied by the metal wire 21 is a wiring region of the upper surface. A region on the upper surface other than the wiring region is a non-wiring region. The pad assemblies 22 are disposed in the non-wiring region.

As shown in FIGS. 13C and 13D, the pin assembly 30 is disposed on the lower surface of the substrate 10 and connected to the circuit assembly 2 through a conductive hole 101 penetrating through the substrate 10. The pin assembly 30 includes multiple pins 300 and multiple pin wires 310, and a pin wire 310 connects the conductive hole 101 to a pin 300.

At least one RGB chip group 5 is provided. The number of pad assemblies 22 is equal to the number of RGB chip groups 5, and each RGB chip group 5 is correspondingly disposed on a respective pad assembly 22.

As shown in FIGS. 13A and 13B, the metal identifier 6 is disposed on the upper surface of the substrate 10, used for identifying the position of the RGB chip group 5 in the substrate 10. The metal identifier 6 is fixed in the non-wiring region, and connected to the metal wire 21 by a connecting metal wire 60. The metal identifier 6 is specifically circular or may be triangular, elliptical, rectangular, or the like. The metal identifier disposed in the LED display device is firmly combined with a substrate and is not prone to fall off so that the metal identifier can reliably perform the function of positioning chips.

The black ink layer 7 is disposed on the upper surface of the substrate 10 and covers the metal wire 21, the connecting metal wire 60, and conductive holes 101 connected to the metal wire 21. For further optimization, the black ink layer 7 covers only the wiring region but does not cover the non-wiring region, as shown in FIG. 13A. The black ink layer 7 can increase the contrast ratio of the device.

The encapsulant is disposed on the upper surface of the substrate 10 and covers the black ink layer 7 and the non-wiring region to encapsulate the black ink layer, the at least one RGB chip group 5, and the metal identifier 6.

Since the black ink layer 7 does not cover the non-wiring region, the encapsulant in the non-wiring region may be in direct contact with and combined with the upper surface of the substrate 10. Thus, the adhesiveness between the encapsulant and the substrate 10 is improved and vapor from the outside is prevented from entering the device via the gap between the black ink layer 7 and the substrate 10, thereby improving the reliability of the device.

As shown in FIGS. 13C and 13D, solder resist ink includes the solder resist layer 91 and the white ink layer 93. The solder resist layer 91 is disposed on the lower surface of the substrate 10, is filled among all the pins 300, and covers the connecting wire 400 and the pin wires 310.

The solder resist layer 91 is provided with a window 92 for accommodating the white ink layer 93. The white ink layer 93 is used for identifying the position of the pin 300 in the substrate 10, disposed in the window 92 of the solder resist layer 91, and directly fixed on the lower surface of the substrate 10. No connecting wire 400 and no pin wire 310 exist in the region where the white ink layer 93 is fixed.

For further optimization, the area of the white ink layer 93 is less than one third of the area of the substrate 10.

More specifically, in some embodiments, the white ink layer 93 and an adjacent pin 300 are disposed in the same window 92 of the solder resist layer 91, and the area of the white ink layer 93 is less than the area of the pin 300. In another embodiment, the window 92 with which the solder resist layer 91 is provided may be completely filled with the white ink layer 93.

The substrate 10 is generally made of an insulating resin material. The black ink layer 7 is made of black epoxy resin. The white ink layer 93 is made of insulating white ink, and the solder resist layer 91 is made of insulating green ink (solder resist ink). The encapsulant is made of transparent epoxy resin.

The circuit assembly 2, the pin assembly 30, the connecting wire 400, the conductive holes 101, the metal identifier 6, and the connecting metal wire 60 are specifically made of copper, and hole walls of the conductive holes 101 are plated with copper layers.

As shown in FIG. 13B, the RGB chip group 5 includes a red LED chip 51, a green LED chip 52, and a blue LED chip 53. Preferably, each of the red LED chip 51, the green LED chip 52, and the blue LED chip 53 is a flip chip. Compared with a face-up chip, the flip chip is used and can increase the distance between a positive electrode and a negative electrode, reducing the risk of metal migration. In addition, compared with a face-up mounting process, a flip-chip process can reduce wire-soldering procedures. Further, a paste dispensing process is replaced by a high-efficiency printing process, and a long-term bake hardening process is replaced by a high-efficiency reflow process so that process efficiency can be effectively improved and manufacturing costs can be reduced.

Correspondingly, the pad assembly 22 includes three pairs of pads, the three pairs of pads are correspondingly connected to the red LED chip 51, the green LED chip 52, and the blue LED chip 53, respectively. Two pads in each pair of pads are axisymmetrically disposed, and midlines of the two pads in each pair are on the same straight line.

For the chip with small size, two pads connecting each chip are arranged along a straight-line during die-bonding performed through the reflow process so that midlines of the electrical wires connected to the two pads are on the same straight line. Thus, a solder paste flows along an opposite direction, generating an acting force in the opposite direction and preventing the flip chip from being folded or twisted.

More specifically, referring to FIG. 13B, the LED display device includes four RGB chip groups 5 and four pad assemblies 22, where the four RGB chip groups 5 are arranged in an array with two rows and two columns on the upper surface of the substrate 10, and a blue LED chip 53, a green LED chip 52, and a red LED chip 51 in each RGB chip group 5 are sequentially aligned and arranged at intervals in one column from top to bottom.

The number of the conductive holes 101 is twelve, and the conductive holes 101 include two common-electrode conductive holes 101a that are disposed at the top of the substrate 10 and the bottom of the substrate 10, respectively.

The negative electrode of each chip in the upper left RGB chip group 5 is connected to the common-electrode conductive hole 101a at the top by the pad assembly 22 and the metal wire 21, and the negative electrode of each chip in the upper right RGB chip group 5 is also connected to the common-electrode conductive hole 101a at the top by the pad assembly 22 and the metal wire 21.

Optionally, the metal identifier 6 is disposed on the upper side of the substrate 10 and connected to the common-electrode conductive hole 101a at the top by the connecting metal wire 60.

Referring to both FIG. 13B and FIG. 13D, the LED chip of a relatively small size is suitable for the LED display device in some embodiments, where the pad for fixing the LED chip has a relatively small area, and it is difficult to provide the conductive hole 101 at the position that coincides with the pad along an orthographic projection direction in the substrate 10. The conductive hole 101 in some embodiments can be led out only by the metal wire 21 to the wiring region for configuration, the pad cannot be directly connected to the pin assembly 30 on the lower surface through the conductive hole 101 and needs to be connected to the conductive hole 101 by the metal wire 21, so as to be connected to the pin assembly 30 on the lower surface.

A display panel in some embodiments includes multiple LED display devices so that the quality of the display panel is improved.

In the LED display device array provided by the present application, the connecting wire with a straight connecting segment is disposed between the two adjacent pins that are misaligned, and it is ensured that the straight connecting segment intersecting with the cutting line on the substrate is perpendicular to the cutting line so that the connecting wire has an even cut after being cut along the cutting line, and the burr defect is avoided.

In the LED display device provided by the present application, the metal identifier is configured to be connected to the metal wire through the connecting metal wire so that the connection strength between the metal identifier and the substrate is improved, and the metal identifier is prevented from falling off from the substrate when the substrate is cleaned. Thus, the stability of an identification point is improved, thereby improving a die-bonding yield.

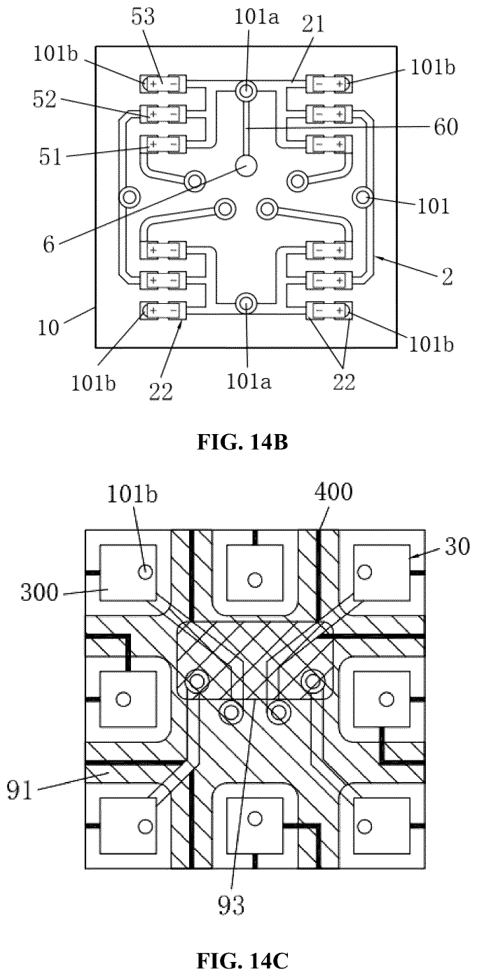

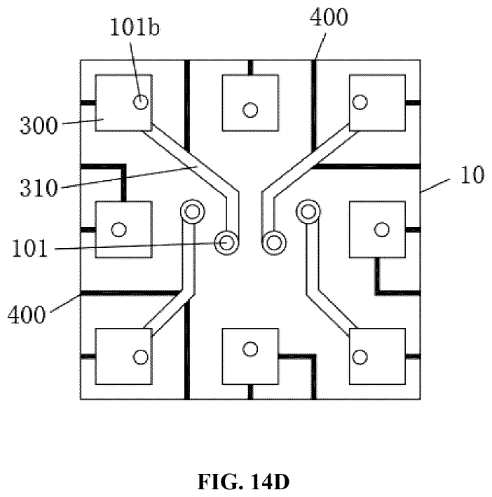

FIGS. 14A to 14D show an LED display device in some embodiments.

To facilitate clear observation of the arrangement of various components on both the upper and the lower surfaces of the substrate 10, FIG. 14A shows the upper surface of the LED display device omitting an encapsulant, where the portion filled with oblique lines in this figure represents a black ink layer 7, FIG. 14B shows the upper surface of the LED display device omitting the encapsulant and the black ink layer 7, FIG. 14C shows the lower surface of the LED display device, where the large-area portion filled with oblique lines in this figure represents a solder resist layer 91, and the small-area portion filled with oblique lines represents a white ink layer 93, and FIG. 14D shows the lower surface of the LED display device omitting the solder resist layer 91 and the white ink layer 93.

The LED display device in some embodiments is basically the same as the LED display device in the preceding embodiments, and the main differences between the LED display device in the following embodiments and the LED display device in the preceding embodiments are described below.

The white ink layer 93 in some embodiments is disposed on the surface of the solder resist layer 91, and a metal wire 21 and conductive holes 101 are arranged in a different manner.

Specifically, referring to both FIG. 14C and FIG. 14D, the white ink layer 93 covers the surface of the solder resist layer 91, and the area of the white ink layer 93 is less than one fourth of the area of the substrate 10.

Referring to both FIG. 14B and FIG. 14D, the LED chip of a relatively large size is suitable for the LED display device, where the pad for fixing the LED chip has a relatively large area, and a pad conductive hole 101b can be provided at the position that coincides with the pad along an orthographic projection direction in the substrate 10. Therefore, the pad is directly connected to a pin assembly 30 on the lower surface through the pad conductive hole 101b, and the pad conductive hole 101b does not need to be led out by the metal wire 21 to a wiring region for configuration.

Compared with FIG. 13B in the preceding embodiments, FIG. 14B shows that, the positive electrode of a blue LED chip 53 in the upper left RGB chip group 5 and the positive electrode of a blue LED chip 53 in the upper right RGB chip group 5 are connected to the pin assembly 30 on the lower surface by corresponding pads and pad conductive holes 101b, and the positive electrode of a red LED chip 51 in the lower left RGB chip group 5 and the positive electrode of a red LED chip 51 in the lower right RGB chip group 5 are connected to the pin assembly 30 on the lower surface by corresponding pads and pad conductive holes 101b.

A display panel in some embodiments includes multiple LED display devices so that the quality of the display panel is improved.

Apparently, the preceding embodiments of the present application are only examples for illustrating the present application clearly and are not intended to limit embodiments of the present application. Those of ordinary skill in the art can make various apparent modifications, adaptations, and substitutions without departing from the scope of the present application. There is no need and no way to exhaust all of the embodiments here. Any modification, equivalent substitution, improvement, or the like made within the spirit and principle of the present application is within the scope of the claims of the present application.

What is claimed is:

1. A light-emitting diode (LED) display device array, comprising a substrate,
at least two display units disposed on an upper surface of the substrate, and
at least two pin assemblies disposed on a lower surface of the substrate and in one-to-one correspondence with the at least two display units,
wherein a cutting line is disposed on the substrate between any two adjacent pin assemblies;
each of the at least two pin assemblies comprises at least two pins, and the at least two pins comprise a first pin and a second pin;
a first pin in one of the at least two pin assemblies is misaligned with a second pin in an adjacent one of the at least two pin assemblies, and the first pin and the second pin are connected to each other through a connecting wire; and
the connecting wire has a linear connecting segment, and the connecting segment of the connecting wire intersects with the cutting line and is perpendicular to the cutting line.

2. The LED display device array according to claim 1, wherein
a length of the connecting segment of the connecting wire is greater than a width of the cutting line.

3. The LED display device array according to claim 2, wherein
the connecting wire further has a first pin connecting segment and a second pin connecting segment;
an end of the first pin connecting segment is connected to the first pin, and another end of the first pin connecting segment is connected to an end of the connecting segment; and
an end of the second pin connecting segment is connected to the second pin, and another end of the second pin connecting segment is connected to another end of the connecting segment.

4. The LED display device array according to claim 3, wherein
each of the first pin connecting segment and the second pin connecting segment is a straight line or a curve.

5. The LED display device array according to claim 3, wherein
each of the first pin connecting segment and the second pin connecting segment is a straight line, and the first pin connecting segment and the second pin connecting segment are perpendicular to the connecting segment.

6. The LED display device array according to claim 3, wherein
each of the first pin connecting segment and the second pin connecting segment is a straight line; and
the first pin connecting segment is perpendicular to the connecting segment, and the second pin connecting segment is collinear with the connecting segment, or the second pin connecting segment is perpendicular to the connecting segment, and the first pin connecting segment is collinear with the connecting segment.

7. The LED display device array according to claim 1, further comprising a cover plate;
wherein the cover plate covers the upper surface of the substrate;
the cover plate is provided with through holes, and the through holes form accommodation cavities with the substrate, the accommodation cavities are in one-to-one correspondence with the display units; and
the at least two display units comprises at least one pixel assembly, and each of the at least one pixel assembly is disposed in a respective accommodation cavity.

8. The LED display device array according to claim 7, wherein
an accommodation cavity is filled with an encapsulant, and the encapsulant is transparent and black.

9. The LED display device array according to claim 7, wherein
an accommodation cavity is filled with an encapsulant, and the encapsulant comprises a first encapsulant layer at a lower portion of the accommodation cavity and a second encapsulant layer at an upper portion of the accommodation cavity, wherein the first encapsulant layer is transparent, and the second encapsulant layer is transparent and black.

10. The LED display device array according to claim 7, wherein
at least one pad assembly is disposed on the upper surface of the substrate, the at least one pad assembly is in one-to-one correspondence with the at least one pixel assembly, each of the at least one pixel assembly is die-bonded on a respective pad assembly, and a periphery of each of the at least one the pad assembly in the respective accommodation cavity is a circular structure adapted to a bottom of the respective accommodation cavity.

11. The LED display device array according to claim 10, wherein
the substrate is provided with a conductive hole penetrating through the upper surface of the substrate and the lower surface of the substrate, and a pad assembly of the at least one pad assembly and a pin assembly of the at least two pin assemblies are electrically connected to each other by the conductive hole;
the lower surface of the substrate is divided into an insulating region and a non-insulating region; and
the pin assembly further comprises a pin wire configured to connect a pin of the at least two pins to the conductive hole, the pin is disposed in the non-insulating region, the insulating region is covered with solder resist ink, and the solder resist ink covers the pin wire in the insulating region.

12. A light-emitting diode (LED) display device, wherein the LED display device is formed by cutting the LED display device array according to claim 1 along the cutting line, and the LED display device comprises:
a substrate having an upper surface and a lower surface, wherein the upper surface comprises a wiring region and a non-wiring region;
a circuit assembly disposed on the upper surface of the substrate and comprising a metal wire and at least one pad assembly that are connected to each other, wherein the metal wire is disposed in the wiring region, and the at least one pad assembly is disposed in the non-wiring region;
a pin assembly disposed on the lower surface of the substrate and connected to the circuit assembly through a conductive hole penetrating through the substrate;
at least one RGB chip group correspondingly disposed on the at least one pad assembly respectively; and
a metal identifier used for identifying a position of the at least one RGB chip group in the substrate, fixed in the non-wiring region, and connected to the metal wire by a connecting metal wire.

13. The LED display device according to claim 12, further comprising a black ink layer, wherein the black ink layer is disposed on the upper surface of the substrate and covers the metal wire and the connecting metal wire.

14. The LED display device according to claim 12, wherein each of the at least one RGB chip group comprises a red LED chip, a green LED chip, and a blue LED chip, wherein each of the red LED chip, the green LED chip, and the blue LED chip is a flip chip.

15. The LED display device according to claim 14, wherein each of the at least one pad assembly comprises three pairs of pads, the three pairs of pads are correspondingly connected to the red LED chip, the green LED chip, and the blue LED chip respectively, two pads in each pair of pads are axisymmetrically disposed, and midlines of the two pads in the each pair are on a same straight line.

16. The LED display device according to claim 14, wherein the conductive hole comprises a common-electrode conductive hole, the common-electrode conductive hole is connected to electrodes of same polarity of all chips in the at least one RGB chip group by the metal wire and the pad assembly.

17. The LED display device according to claim 16, wherein the metal identifier is connected to the common-electrode conductive hole by the connecting metal wire.

18. A display panel, comprising a light-emitting diode (LED) display device, wherein the LED display device is formed by cutting the LED display device array according to claim 1 along the cutting line; and
wherein the LED display device comprises:
a substrate having an upper surface and a lower surface, wherein the upper surface comprises a wiring region and a non-wiring region;
a circuit assembly disposed on the upper surface of the substrate and comprising a metal wire and at least one pad assembly that are connected to each other, wherein the metal wire is disposed in the wiring region, and the at least one pad assembly is disposed in the non-wiring region;
a pin assembly disposed on the lower surface of the substrate and connected to the circuit assembly through a conductive hole penetrating through the substrate;
at least one RGB chip group correspondingly disposed on the at least one pad assembly respectively; and
a metal identifier used for identifying a position of the at least one RGB chip group in the substrate, fixed in the non-wiring region, and connected to the metal wire by a connecting metal wire.
